(19) United States
(12) Patent Application Publication
(10) Pub. No.: US 2025/0260390 A1
(43) Pub. Date: Aug. 14, 2025

(54) RADIO FREQUENCY MODULE WITH TUNABLE ACOUSTIC FILTER PASSBAND

(71) Applicant: Skyworks Solutions, Inc., Irvine, CA (US)

(72) Inventors: Grant Darcy Poulin, Carp (CA); Hichem Ben Hedi Abdallah, Andover, MA (US); Wesley John Boyd, Coal Valley, IL (US); Scott J. Smith, Hollis, NH (US); Timothy Joseph McGovern, Andover, MA (US)

(21) Appl. No.: 19/051,067

(22) Filed: Feb. 11, 2025

Related U.S. Application Data
(60) Provisional application No. 63/552,598, filed on Feb. 12, 2024.

(51) Int. Cl. H03H 9/70

(52) U.S. Cl. CPC H03H 9/706; H03H 2210/015; H03H 2210/025; H03H 2210/026

(57) ABSTRACT

An acoustic filter assembly for operating at a target band including multiple spaced sub-target bands. The filter assembly includes a first filter that passes a first band and a second filter that passes a second band. The first filter and the second filter have a transition band between the first band and the second band that is wider than the spacing between the sub-target bands. An interface receives a control signal that controls the transition band to be shifted between a first position and a second position, such that an upper part of a lower sub-target band is covered by the first band in the first position, and a lower part of an upper sub-target band is covered by the second band in the second position.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of the invention relate to electronic systems, and in particular, to acoustic filter assemblies for use in radio frequency (RF) electronics.

### Description of the Related Technology

Radio frequency (RF) is a common term for a range of frequency of electromagnetic radiation typically used to produce and detect radio waves. Such a range can be from about 30 kHz to 300 GHz. Wireless communication devices often include front-end circuitry for processing or conditioning RF signals at an incoming or outgoing frequency or signal port. RF front-end modules may be components of receiver, transmitter, or transceiver systems associated with a wireless device.

RF front-end design may include a number of considerations, including complexity, substrate compatibility, performance, and integration. It can be desirable for wireless devices to support multiple wireless technologies. For instance, modern mobile phones and other wireless devices send and receive growing quantities of electronic data including email, electronic documents, data communicated during web browsing sessions, and the like, often by incorporating a wireless local area network (WLAN) interface. Modern devices often also support wireless connection to other electronic devices that are local to the user, including wireless headsets, ear pieces, watches, and other so called “wearable” devices. For instance, some wireless devices support Bluetooth communication, and can connect to Bluetooth capable wearable devices, or other Blue-tooth capable devices in proximity to the wireless device.

### SUMMARY

In some aspects, the techniques described herein relate to an acoustic filter assembly for operating at a target band including multi sub-target bands and a spacing between the multi sub-bands, the acoustic filter assembly including: a first filter configured to allow signals received via an antenna node to pass at a first band; a second filter configured to allow the signals received via the antenna node to pass at a second band, the first filter and the second filter being configured to have a transition band between the first band and the second band, the transition band being wider than the spacing of the target band; and an interface configured to receive a control signal that controls the transition band to be shifted between a first position and a second position, an upper part of a lower sub-target band being covered by the first band in the first position, and a lower part of an upper sub-target band being covered by the second band in the second position.

In some aspects, the techniques described herein relate to an acoustic filter assembly wherein the width of the transition band is less than or equal to 110 MHz.

In some aspects, the techniques described herein relate to an acoustic filter assembly wherein, in the first position, a lower edge of the transition band is aligned with a lower end of the spacing.

In some aspects, the techniques described herein relate to an acoustic filter assembly wherein, in the second position, an upper edge of the transition band is aligned with an upper end of the spacing.

In some aspects, the techniques described herein relate to an acoustic filter assembly wherein the target band is used as an unlicensed band.

In some aspects, the techniques described herein relate to an acoustic filter assembly wherein the spacing of the target band is located between 5895 MHz and 5945 MHz.

In some aspects, the techniques described herein relate to an acoustic filter assembly wherein each of the first filter and the second filter includes at least one resonator, which is selectively connected with a reactive element by the control signal to adjust a resonance frequency or an anti-resonance frequency of the resonator.

In some aspects, the techniques described herein relate to an acoustic filter assembly wherein the reactive element is at least one of a capacitor and an inductor.

In some aspects, the techniques described herein relate to an acoustic filter assembly wherein a location of the transition band is shifted using a RF cancellation that involves adding a phase-inverted signal according to the control signal.

In some aspects, the techniques described herein relate to a radio frequency module including: a packaging substrate configured to receive a plurality of components; an acoustic filter assembly for a target band including multi sub-bands and a spacing between the multi sub-bands, the acoustic filter assembly implemented on the packaging substrate, the acoustic filter assembly including a first filter configured to allow signals received via an antenna node to pass at a first band, a second filter configured to allow the signals received via the antenna node to pass at a second band, the first filter and the second filter being configured to have a transition band between the first band and the second band, the transition band being wider than the spacing of the target band, and an interface configured to receive a control signal that controls the transition band to be shifted between a first position and a second position, an upper part of lower sub-target band being covered by the first band in the first position, a lower part of an upper sub-target band being covered by the second band in the second position; and a controller configured to provide the control signal.

In some aspects, the techniques described herein relate to a radio frequency module wherein the radio frequency module is a front-end module.

In some aspects, the techniques described herein relate to a radio frequency module wherein the width of the transition band is less than or equal to 110 MHZ.

In some aspects, the techniques described herein relate to a radio frequency module wherein, in the first position, a lower edge of the transition band is aligned with a lower end of the spacing.

In some aspects, the techniques described herein relate to a radio frequency module wherein, in the second position, an upper edge of the transition band is aligned with an upper end of the spacing.

In some aspects, the techniques described herein relate to a radio frequency module wherein the target band is used as an unlicensed band.

In some aspects, the techniques described herein relate to a radio frequency module wherein the spacing of the target band is located between 5895 MHz and 5945 MHZ.

In some aspects, the techniques described herein relate to a radio frequency module wherein each of the first filter and the second filter includes at least one resonator, which is selectively connected with a reactive element by the control signal to adjust a resonance frequency or an anti-resonance frequency of the resonator.

In some aspects, the techniques described herein relate to a radio frequency module wherein the reactive element is at least one of a capacitor and an inductor.

In some aspects, the techniques described herein relate to a radio frequency module wherein the transition band is switched using a RF cancellation that involves adding a phase-inverted signal according to the control signal.

In some aspects, the techniques described herein relate to a wireless device including: a transceiver configured to generate a radio frequency signal; and a front end system including an acoustic filter assembly for a target band including multi sub-bands and a spacing between the multi sub-bands, the acoustic filter assembly including a first filter configured to allow signals received via an antenna node to pass at a first band, a second filter configured to allow the signals received via the antenna node to pass at a second band, the first filter and the second filter configured such to have a transition band between the first band and the second band, the transition band being wider than the spacing of the target band, and an interface configured to receive a control signal that controls the transition band to be shifted between a first position and a second position, an upper part of lower sub-target band is covered by the first band in the first position, a lower part of an upper sub-target band is covered by the second band in the second position.

In some aspects, the techniques described herein relate to a wireless device wherein the wireless device is an access point (AP) or a mobile device.

In some aspects, the techniques described herein relate to a wireless device wherein the width of the transition band is less than or equal to 110 MHZ.

In some aspects, the techniques described herein relate to a wireless device wherein, in the first position, a lower edge of the transition band is aligned with a lower end of the spacing.

In some aspects, the techniques described herein relate to a wireless device wherein, in the second position, an upper edge of the transition band is aligned with an upper end of the spacing.

In some aspects, the techniques described herein relate to a wireless device wherein the target band is used as an unlicensed band.

In some aspects, the techniques described herein relate to a wireless device wherein the spacing of the target band is located between 5895 MHz and 5945 MHz.

In some aspects, the techniques described herein relate to a wireless device wherein each of the first filter and the second filter includes at least one resonator, which is selectively connected with a reactive element by the control signal to adjust a resonance frequency or an anti-resonance frequency of the resonator.

In some aspects, the techniques described herein relate to a wireless device wherein the reactive element is at least one of a capacitor and an inductor.

In some aspects, the techniques described herein relate to a wireless device wherein the transition band is switched using a RF cancellation that involves adding a phase-inverted signal according to the control signal.

### BRIEF DESCRIPTION OF THE DRAWINGS

FIG. 1 is a schematic block diagram of an example of a wireless device.

FIG. 2 is part of the frequency range that is allocated to the Wi-Fi spectrum, showing UNII-3, UNII-4 and part of UNII-5.

FIG. 3 is a schematic illustration of an access point having two filters directly connected to antennas, when transmitting in the 6 GHz band and simultaneously receiving data from another user in the 5 GHz band. OOB noise from the 6 GHz transmission degrades sensitivity of the 5 GHz receiver. The 6 GHz filter used to reject OOB noise.

FIG. 4 is a schematic illustration of an access point having two filters directly connected to antennas when transmitting in the 5 GHz band and simultaneously receiving data from another user in the 6 GHz band. The 6 GHz filter is used to reject the 5 GHz jamming signal to avoid saturating the 6 GHz LNA.

FIG. 5 illustrates another example of access point that uses two filters, and switches between them.

FIG. 6 is an example of schematic diagram of access point (AP) according to an embodiment of the present disclosure.

FIG. 7A shows an example of filter responses when the transition band is located in the first position.

FIG. 7B shows an example of filter responses when the transition band is located in the second position.

FIG. 8A illustrates an example of an upper passband roll-off of a bandpass filter frequency response and an example of a frequency response of a resonator of the bandpass filter.

FIG. 8B illustrates an example of a resonator with switchable reactive elements.

FIG. 8C shows the frequency response of the resonator of FIG. 8B for different switching configurations.

FIG. 8D shows another example of a resonator with switchable reactive elements.

FIG. 8E shows examples of upper passband roll-off of a bandpass filter frequency response and an example of a frequency response of a resonator of the bandpass filter.

FIG. 8F is a schematic diagram of a ladder filter that includes one or more bulk acoustic wave (BAW) resonators according to an embodiment.

FIG. 8G is schematic diagram of a band pass filter.

FIG. 9A is a schematic diagram of one embodiment of a packaged module.

FIG. 9B is a schematic diagram of a cross-section of the packaged module of FIG. 8A taken along the lines 9B-9B.

FIG. 10 is a schematic diagram of one embodiment of a phone board.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims.

In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

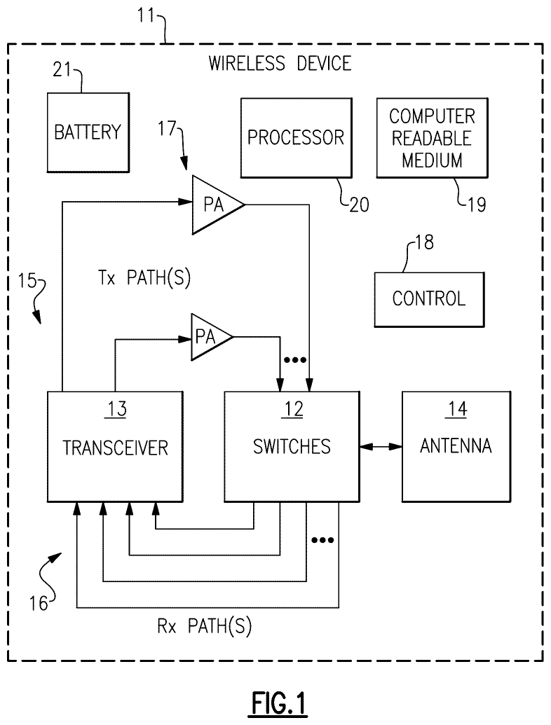

FIG. 1 is a schematic block diagram of an example of a wireless device 11. The wireless device 11 can include a power amplifier bias circuit implementing one or more features of the present disclosure in a control component 18. The power amplifier bias circuit can include a control circuit and a primary biasing circuit.

The example wireless device 11 depicted in FIG. 1 can represent a multi-band and/or multi-mode device such as a multi-band/multi-mode mobile phone. In certain embodiments, the wireless device 11 can include a switch module 12, a transceiver 13, an antenna 14, power amplifiers 17, a control component 18, a computer readable medium 19, a processor 20, and a battery 21.

The transceiver 13 can generate RF signals for transmission via the antenna 14. Furthermore, the transceiver 13 can receive incoming RF signals from the antenna 14.

It will be understood that various functionalities associated with the transmission and receiving of RF signals can be achieved by one or more components that are collectively represented in FIG. 1 as the transceiver 13. For example, a single component can be configured to provide both transmitting and receiving functionalities. In another example, transmitting and receiving functionalities can be provided by separate components.

Similarly, it will be understood that various antenna functionalities associated with the transmission and receiving of RF signals can be achieved by one or more components that are collectively represented in FIG. 1 as the antenna 14. For example, a single antenna can be configured to provide both transmitting and receiving functionalities. In another example, transmitting and receiving functionalities can be provided by separate antennas. In yet another example, different bands associated with the wireless device 11 can be provided with different antennas.

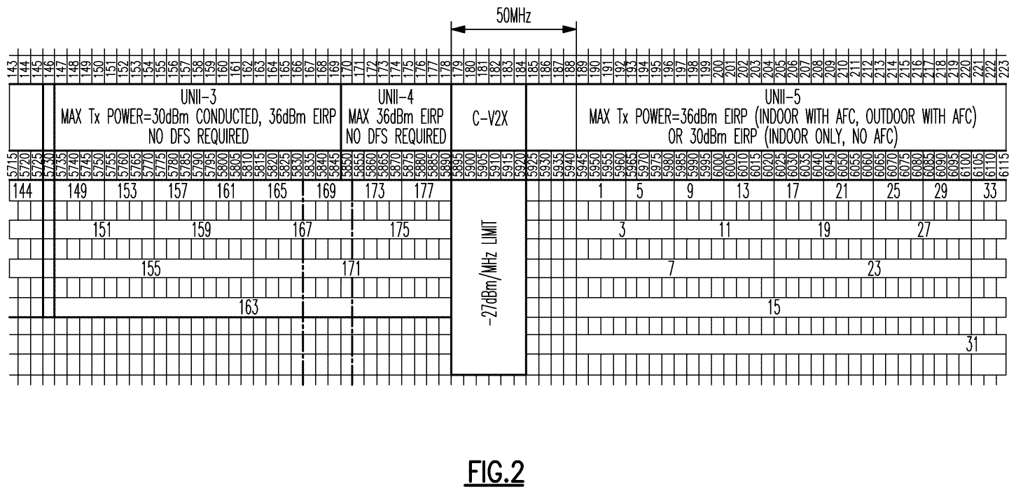

In FIG. 1, one or more output signals from the transceiver 13 are depicted as being provided to the antenna 14 via one or more transmission paths 15. In the example shown, different transmission paths 15 can represent output paths associated with different bands and/or different power outputs. For instance, the two example power amplifiers 17 shown can represent amplifications associated with different power output configurations (e.g., low power output and high power output), and/or amplifications associated with different bands. Although FIG. 2 illustrates a configuration using two transmission paths 15, the wireless device 11 can include more or fewer transmission paths 15.

The power amplifiers 17 can be used to amplify a wide variety of RF signals. For example, one or more of the power amplifiers 17 can receive an enable signal that can be used to pulse the output of the power amplifier to aid in transmitting a wireless local area network (WLAN) signal, such as a WLAN 802.11be signal, or any other suitable pulsed signal. In certain embodiments, one or more of the power amplifiers 17 are configured to amplify a Wi-Fi signal. Each of the power amplifiers 17 need not amplify the same type of signal. For example, one power amplifier can amplify a WLAN signal, while another power amplifier can amplify, for example, another WLAN signal, a Global System for Mobile (GSM) signal, a code division multiple access (CDMA) signal, a W-CDMA signal, a Long Term Evolution (LTE) signal, or a 5G signal.

One or more features of the present disclosure can be implemented in the foregoing example communication standards, modes and/or bands, and in other communication standards.

In FIG. 1, one or more detected signals from the antenna 14 are depicted as being provided to the transceiver 13 via one or more receiving paths 16. In the example shown, different receiving paths 16 can represent paths associated with different bands. Although FIG. 1 illustrates a configuration using four receiving paths 16, the wireless device 11 can be adapted to include more or fewer receiving paths 16.

To facilitate switching between receive and transmit paths, the switch module 12 can be configured to electrically connect the antenna 14 to a selected transmit or receive path. Thus, the switch module 12 can provide a number of switching functionalities associated with an operation of the wireless device 11. In certain embodiments, the switch module 12 can include a number of switches configured to provide functionalities associated with, for example, switching between different bands, switching between different power modes, switching between transmission and receiving modes, or some combination thereof. The switch module 12 can also be configured to provide additional functionality, including filtering and/or duplexing of signals.

FIG. 1 shows that in certain embodiments, a control component 18 can be provided for controlling various control functionalities associated with operations of the switch module 12, the power amplifiers 17, and/or other operating component(s). The control component 18 can be implemented on the same die as the power amplifier 17 in certain implementations. The control component 18 can be implemented on a different die than the power amplifier 17 in some implementations. Non-limiting examples of the control component 18 that include a control circuit and a bias circuit to achieve a desired balance of EVM reduction and OOB emissions are described herein in greater detail.

In certain embodiments, a processor 20 can be configured to facilitate implementation of various processes described herein. For the purpose of description, embodiments of the present disclosure may also be described with reference to flowchart illustrations and/or block diagrams of methods, apparatus (systems) and computer program products. It will be understood that each block of the flowchart illustrations and/or block diagrams, and combinations of blocks in the flowchart illustrations and/or block diagrams, may be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the acts specified in the flowchart and/or block diagram block or blocks.

In certain embodiments, these computer program instructions may also be stored in a computer-readable memory 19 that can direct a computer or other programmable data processing apparatus to operate in a particular manner, such that the instructions stored in the computer-readable memory produce an article of manufacture including instruction means which implement the acts specified in the flowchart and/or block diagram block or blocks. The computer program instructions may also be loaded onto a computer or other programmable data processing apparatus to cause a series of operations to be performed on the computer or other programmable apparatus to produce a computer implemented process such that the instructions that execute on the computer or other programmable apparatus provide instructions for implementing the acts specified in the flowchart and/or block diagram block or blocks.

The battery 21 can be any suitable battery for use in the wireless device 11, including, for example, a lithium-ion battery. Some configurations will not use a battery, and will instead use a DC-DC converter to supply the power to the wireless device.

FIG. 2 shows a portion of the frequency range that is allocated to the Wi-Fi spectrum. In addition, frequency band from 5170-5330 MHz (UNII-1 and UNII-2, and from 5490 to 5730 MHZ (UNII-2c) are allowed, where UNII refers to Unlicensed National Information Infrastructure bands. Recently, an additional Wi-Fi spectrum range that operates from 5850-5895 MHz has been introduced. This spectrum range is known as UNII-4. Wi-Fi operation in the 5945-7125 MHz bands, encompassing UNII-5, 6, 7, and 8 is also allowed.

According to the relevant 802.11be or later standard specifications, all access points need to support simultaneous transmit and receive (STR) operation in at least two frequency bands. A very beneficial STR split is to use the 5 GHz band (UNII-1 to UNII-4 from 5170-5895 MHZ) for the first band and the 6 GHz band (UNII-5 to UNII-8 from 5945-7125 MHZ) as the second band.

According to recent developments, the spacing between these two bands is very narrow, as there is only 50 MHz transition band between the upper edge of UNII-4 and the lower edge of UNII-5. Self-interference between those bands can be a significant problem, where the transmit noise from a transmitter falls into the receive band of the co-located receiver, resulting in reduction of range and throughput. In order to support STR operation, stringent filtering is required in both the 5 GHz bands and the 6 GHz bands.

One of the known ways to resolve self-interference is to place a filter between the FEM and the antenna in each band. In this case, the filter works on the transmitter to reduce out-of-band noise, and on the receiver to attenuate the large out-of-band signal that may jam the receiver.

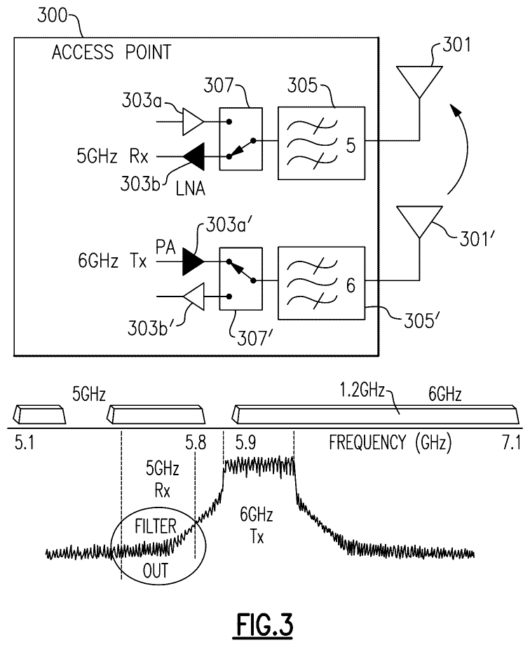

FIGS. 3 and 4 are schematic illustrations of an access point 300 having two filters 305, 305′ directly connected to two antennas 301, 301′. Each antenna 301, 301′ may have separate front end circuitry. However, the bandpass filters 305, 305′ connected to each antenna 301, 301′ may have different passbands: bandpass filter 305 is a 5 GHz bandpass filter whilst bandpass filter 305′ is a 6 GHz bandpass filter. As the front end circuitry for each antenna 301, 301′ may comprise a switch 307, 307′ that can switch between a power amplifier 303a, 303a′ and a low noise amplifier 303b, 303b′, each antenna can transmit and receive.

FIG. 3 illustrates the access point 300 configured with the 6 GHZ antenna 301′ front end circuitry in a transmit path (Tx) configuration and with the 5 GHZ antenna 301 front end circuitry in a receive path (Rx) configuration. That is, bandpass filter 305′ may be connected, by switch 307′, to power amplifier 303a′ and bandpass filter 305 is connected, by switch 307, to low noise amplifier 303b. In this configuration, the 6 GHz bandpass filter 305′ may reject out-of-band (OOB) noise (including noise that is within the 5 GHz passband of bandpass filter 305) that would otherwise be received by antenna 301 and degrade the noise floor and cause desensitization of the 5 GHz receiver signal path.

The access point 300 may work with simultaneous transmission (Tx) and receiving (Rx) (STR) in multiple frequency bands. While the access point 300 as illustrated includes two antennas, two filters, and two switches, two power amplifiers, and two low noise receivers, for example, it would be appreciated by one of ordinary skill in the art that the number of the components can vary, as described herein. As illustrated, access point 300 may transmit and receive signals simultaneously in 5 GHz and 6 GHz bands in certain embodiments. One of ordinary skill in the art would recognize that the bands with which an embodiment of the access point 300 can work are not limited to the 5 GHz and 6 GHz bands.

As but one example, FIG. 3 shows an example of 5 GHz and 6 GHZ frequency bands wherein OOB noise can be observed. That is, because the 5 GHZ and 6 GHZ bands are relatively close to each other in the frequency spectrum, and because there is finite isolation between the 6 GHz Antenna 301′ and the 5 GHz antenna 301, the OOB noise from the 6 GHz Tx chain may show up as in-band noise in the 5 GHz Rx chain. For example, the OOB noise from the 6 GHz Tx chain transmitted at the antenna 301′ can be received by the antenna 301, pass through the filter 305 and the switch 307, and be amplified for processing by the LNA 303b. Because the OOB noise from the 6 GHz transmitter falls in the passband of the 5 GHz receiver, the 5 GHz bandpass filter 305 is unable to remove the noise, and this noise will cause de-sensitization of the 5 GHz receive chain. The only way to eliminate the OOB noise from the 6 GHz transmitter is to filter it out with filter 305′.

FIG. 4, on the other hand, illustrates the access point 300 configured with the 5 GHz antenna 301 front end circuitry in a transmit configuration and with the 6 GHz antenna 301′ front end circuitry in a receive path configuration. That is, bandpass filter 305′ is connected, by switch 307′, to low noise amplifier 303b′ and bandpass filter 305 is connected, by switch 307, to power amplifier 303a. In this configuration, the 6 GHz bandpass filter 305′ rejects 5 GHz signal leakage that would otherwise saturate low noise amplifier 303b′ resulting in desensitization.

It is highly desirable to have a pair of filters that can operate to allow simultaneous UNII-4/5 operation. However, these filters will be extremely challenging to fabricate. It is projected that the required 5 GHz filter will need to pass a signal at 5895 MHZ with less than 2 dB insertion loss, and give rejection of more than 70 dB at 5945 MHZ, only 50 MHz away. It is projected that the required 6 GHz filter will need to pass a signal at 5945 MHz with less than 2 dB insertion loss and give rejection of more than 70 dB at 5895 MHZ, only 50 MHz away. Achieving more than 70 dB rejection with only a 50 MHz transition band, and achieving this over process and temperature, may not be possible.

Most solutions that currently exist do not use UNII-4, with the 5 GHz radio operating from UNII-1 to UNII-3 and the 6 GHz radio operating from UNII5-8. UNII-4 is therefore used as part of the transition band, and the transition band is therefore 110 MHZ wide. Filters with 110 MHz transition band are achievable. However, this means that UNII-4 is not useable. Attempting to use UNII-4 for transmission of 5 GHz signals would cause too much attenuation leading to low transmit power. In addition, the 6 GHz receiver would have insufficient filtering of the 5 GHz Tx signal operating in UNII-4 resulting in degraded receiver linearity and very high packet error rates.

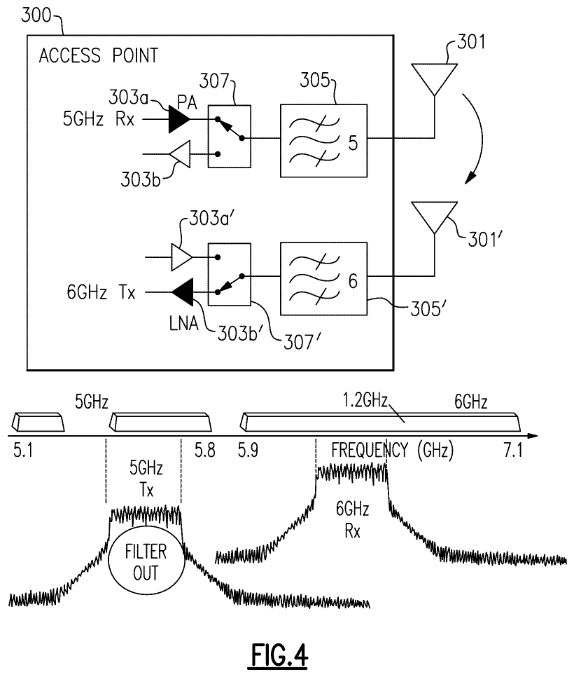

FIG. 5 illustrates another example of access point that uses two filters 505, 505′, and switches 507a, 507b between them. This configuration has been demonstrated in U.S. Pat. No. 11,476,824 B2. One filter 505 operates only in UNII-3 and UNII-4 and has a narrow passband, and a narrow transition band. The second filter 505′ operates in UNII-1 to UNII-2C, has a wide passband, and a much wider transition band. These two switched filters are paired with similar filters in the 6 GHz band (one operates in the lowest 160 MHz of UNII-5, has a 160 MHz passband, and a narrow transition band. The second operates in the remainder of the 6 GHz band and has a wider transition band). However, this approach has several issues: It requires two filters and two switches for each band, and for each MIMO stream. This means that it is very expensive to implement. Second, one of the switches is positioned after the filter, and it therefore needs very high linearity. Finally, the requirement to use two switches means that the loss of this architecture is high, resulting in poor efficiency.

In this description, it is proposed to be able to use both UNII-4 and UNII-5 channels. To do so it may be desirable to have BAW filters with an extremely narrow transition band, e.g., of 50 MHz. According to the present invention, BAW filters with a 110 MHz wide transition band can be used, but embodiments allow for switching the location of the transition band based on the desired Tx and Rx channels to be used. The exact location of the transition band can be altered using techniques such as switched inductors and/or capacitors applied to select resonators in each BAW filter, or using a cancellation technique, for example.

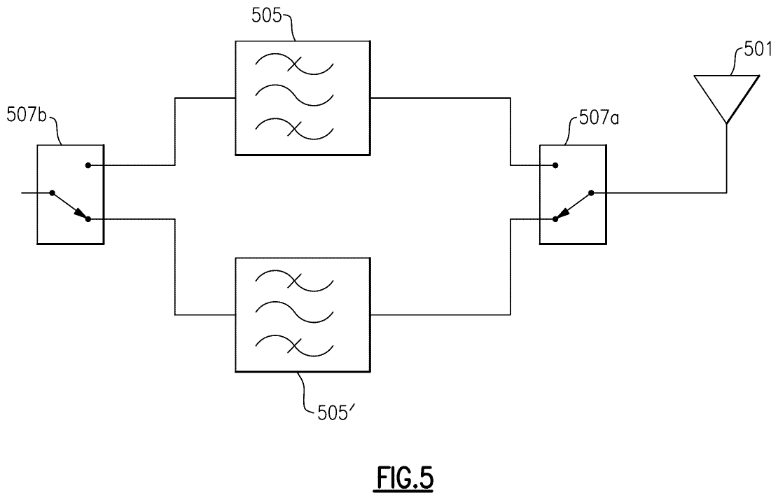

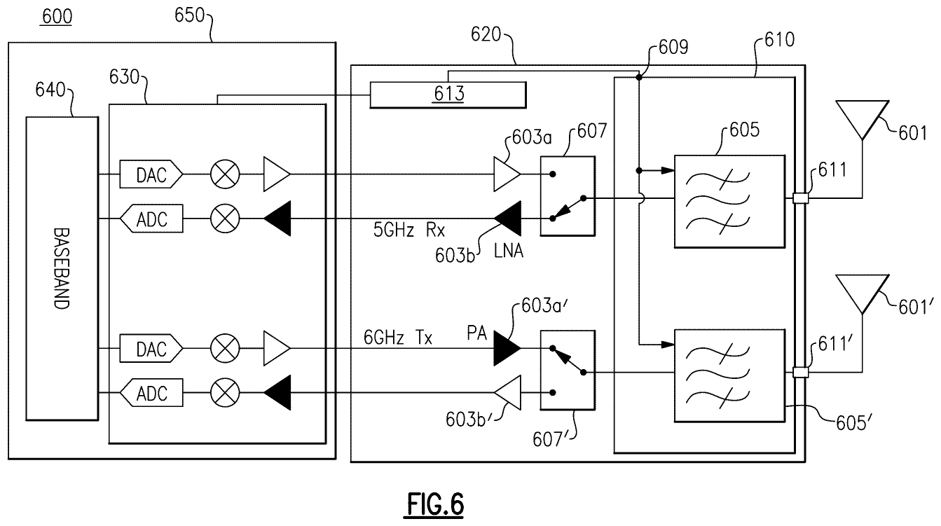

FIG. 6 is an example of schematic diagram of an access point (AP) according to an embodiment of the present disclosure. As shown in FIG. 6, the AP 600 may include a filter assembly 610. In this description, the AP 600 may be also referred to as a wireless device. The schematic diagram for the AP 600 may be applied to a mobile device. The filter assembly 610 is provided to operate in a target band shown in FIG. 2. The target and according to the present disclosure may include multi sub-bands and a spacing between the multi sub-bands. In one example, the spacing of the target band may have a width of 50 MHz. The spacing of the target band may be located between 5895 MHz and 5945 MHZ. The target band may have two parts, that is, a lower sub-target band that is below the spacing and an upper sub-target band that is above the spacing.

The filter assembly 610 may include a first filter 605 and a second filter 605′. The first filter 605 and the second filter 605′ may be BAW filters. The first filter 605 and the second filter 605′ may be bandpass filers. The first filter 605 may be configured to allow signals received via an antenna node 611 to pass at a first band. The second filter 605′ may be configured to allow the signals received via the antenna node 611′ to pass at a second band. The first band may cover UNII-3 and UNII-4, and the second band may cover UNII-5. The first band may cover at least a part of 5 GHz frequency region, and the second band may cover at least a part of 6 GHz frequency region.

The antenna nodes 611, 611′ may be connected to the antenna 601, 601′ respectively. The first filter 605 and the second filter 605′ may be configured such to have a transition band between the first band and the second band. The transition band may be wider than the spacing of the target band. For example, the transition band may have a width of 110 MHZ.

The filter assembly 610 may further include the interface 609 configured to receive a control signal that controls the transition band to be shifted between a first position and a second position. In the first position, a lower edge of the transition band may be aligned with a lower end of the spacing such that the first band covers the upper part of a lower sub-target band. That is, the location of lower edge of the transition band may be adjusted to move toward the lower end of the spacing. In the second position, an upper edge of the transition band may be aligned with an upper end of the spacing such that the second band covers the lower part of a upper sub-target band. That is, the location of upper edge of the transition band may be adjusted to move toward the upper end of the spacing. In both the first position and the second position, the transition band between the first band and the second band may have a substantially same width. That is, the width of the transition band may be maintained similarly as approximately 110 MHz. Thus, it is not necessary to adjust the width of the transition band, and therefore the self-interference can be minimized using practical BAW filters, provided that the channels in the 5 and 6 GHz bands are properly selected.

For example, in the first position, the 5 GHz BAW is configured to pass UNII-1 to UNII-4 channels, whereas the 6 GHz BAW is configured to pass signals at least 60 MHz above the UNII-5 lower band edge to the top edge of UNII-8, and the channels in the lowest 60 MHz of UNII5 are not used. In the second position, the 5 GHz BAW is configured to pass UNII-1 to UNII-3 channels, whereas the 6 GHz BAW is configured to pass UNII5 to UNII-8 and the UNII-4 channels are not used.

According to an embodiment of the present disclosure, each of the first filter 605 and the second filter 605′ may include at least one resonator, which is selectively connected with a reactive element by the control signal to adjust a resonance frequency or an anti-resonance frequency of the resonator. The reactive element may be an inductor and/or a capacitor. For example, the resonator may be connected in series with the inductor and connected in parallel with the conductor. The inductor may be further connected in parallel with a switch and the capacitor may be further connected in series with another switch. By controlling each of the switches, the resonance frequency and the anti-resonance frequency of the resonator can be adjusted. However, the implementation of shifting the transition band is not limited thereto. Any measures to improve rolloff stiffness of the filter response can be applied to be able to control the location of the transition band.

For example, a RF cancellation technique can be also used for shifting the transition band. More specifically, the RF cancellation may include sampling the desired signal, adjusting its amplitude, inverting its phase, and then adding it back to the original signal.

According to an embodiment of the present disclosure, the AP 800 may further include a front-end module 620. The front-end module 620 may include the filter assembly 610 described above. The front-end module 620 may be configured to generate the control signal to be provided to the filter assembly 620. These control signals can be sent over the interface 609, for example digital interface, using dedicated GPIOs, over a SPI or I2C serial bus, or over a MIPI interface if so equipped.

The front-end module 620 may include a controller 613 configured to generate the control signal. The controller 613 may receive a signal from a SoC (system on chip) 650. More specifically, the filter tuning can be controlled by SoC 650, which comprises the OFDM generator 640 and the RF transceiver 630. The SoC 650 is capable of knowing exactly what channels are being used and it will eventually cause to send control signals to the filter to properly configure it. In some embodiments, the front-end module 620 can provide the the SoC 650 an indication of the capability of the front-end module 620, such as to inform the SoC 650 of the capability of the front-end module 620 to allow for UNII-4/5 with a wider transition band using the filter tuning techniques described herein.

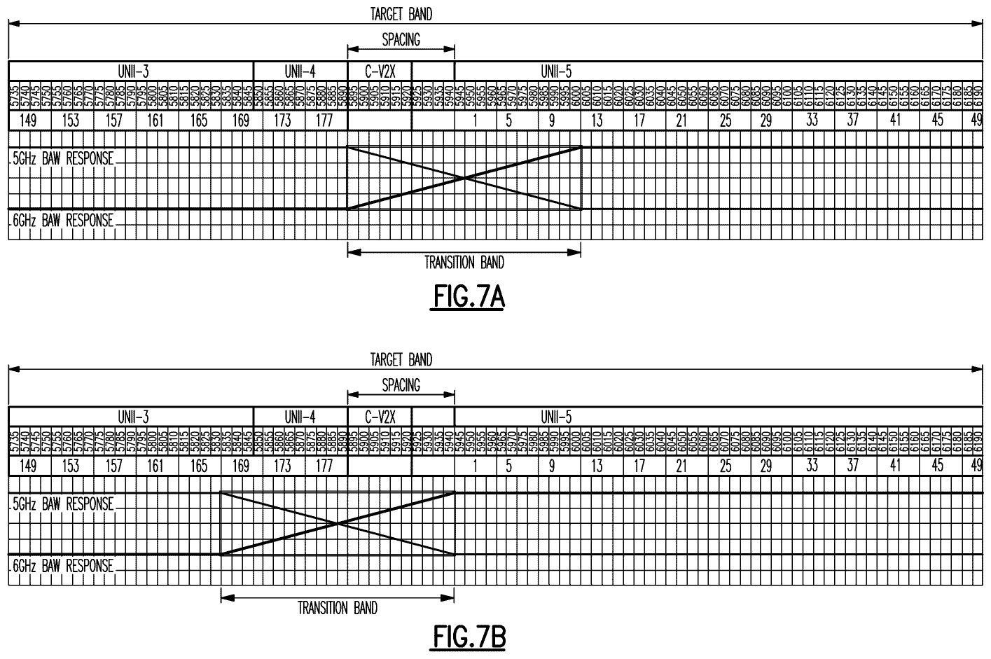

FIG. 7A shows an example of filter responses when the transition band is located in the first position. As shown in FIG. 7A, in the first position, a lower edge of the transition band may be aligned with a lower end of the spacing. When it is desired to transmit or receive in the UNII-4 band (in 5 GHz channel 169, 173, 177 between 5835 and 5895 MHZ), the two filters are both switched to operate tuned 60 MHz higher in frequency, as shown in FIG. 7A, thereby facilitating operation in UNII-4 band. Receiving in the lower part of the UNII-5 band is, however, may not be practical, e.g., where the 6 GHz filter has significant loss. Attempting to transmit in the lower part of the UNII-5 band may result in severe jamming of all 5 GHz channels due to the lack of adequate 5 GHz filtering. The baseband controller or other appropriate component can control the state of the filters, and can also control the channel combination used during this mode of operation, e.g., to ensure that certain lower UNII-5 channels (e.g., 20 MHz channels 1, 5, 9) are not used when operating in UNII-4.

FIG. 7B shows an example of filter responses when the transition band is located in the second position. In the second position, an upper edge of the transition band may be aligned with an upper end of the spacing. When it is desired to transmit or receive in the lower part of the UNII-5 band (in 6 GHz channel 1, 5, or 9 between 5945 and 6005 MHZ), the two filters are configured as shown below in FIG. 7B, thereby facilitating operation in the lower part of the UNII-5 band. Receiving signals in the UNII-4 band may not be practical since the 5 GHz filter can have significant loss. Attempting to transmit in the UNII-4 band may result in severe jamming of all 6 GHz channels due to the lack of adequate 6 GHz filtering. The baseband controller or other appropriate component can control the state of the filters, and can also control the channel combination used during this mode of operation, e.g., to ensure that UNII-4 is not used while operating in UNII-5 channel 1, 5, or 9.

According to the present disclosure, although the spacing between sub target bands is decreased, it is not necessary to reduce the transition band and therefore the self-interference can be prevented using BAW filters with 110 Mhz transition bands.

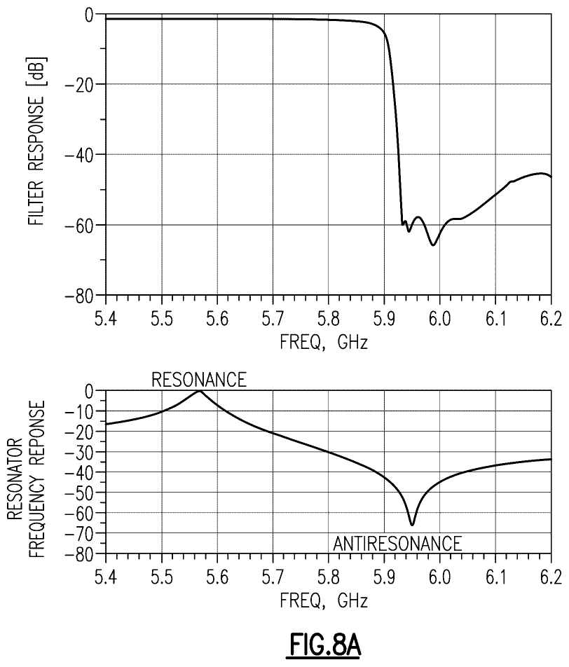

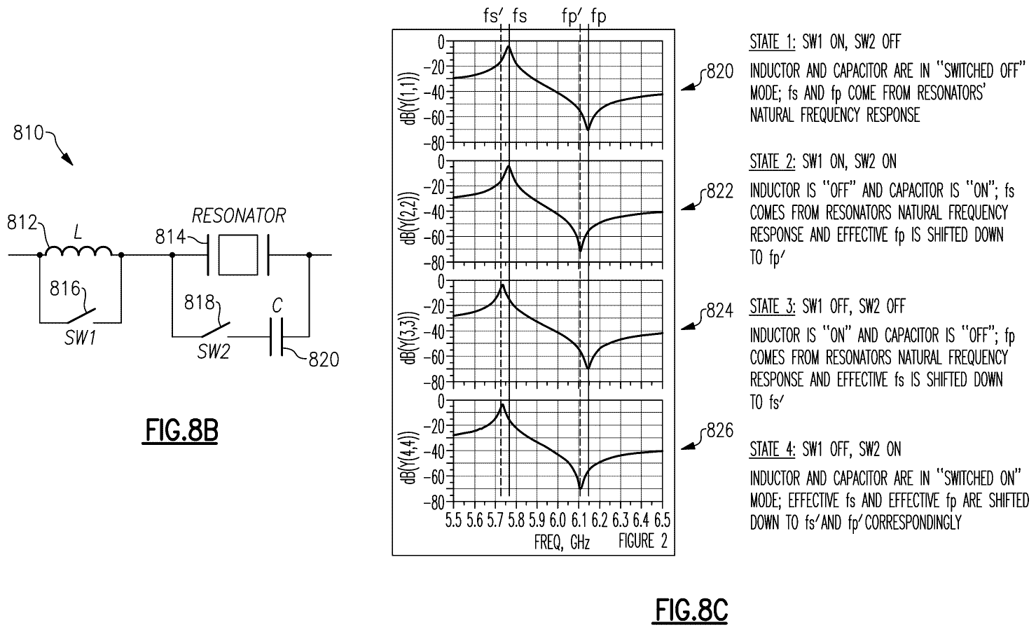

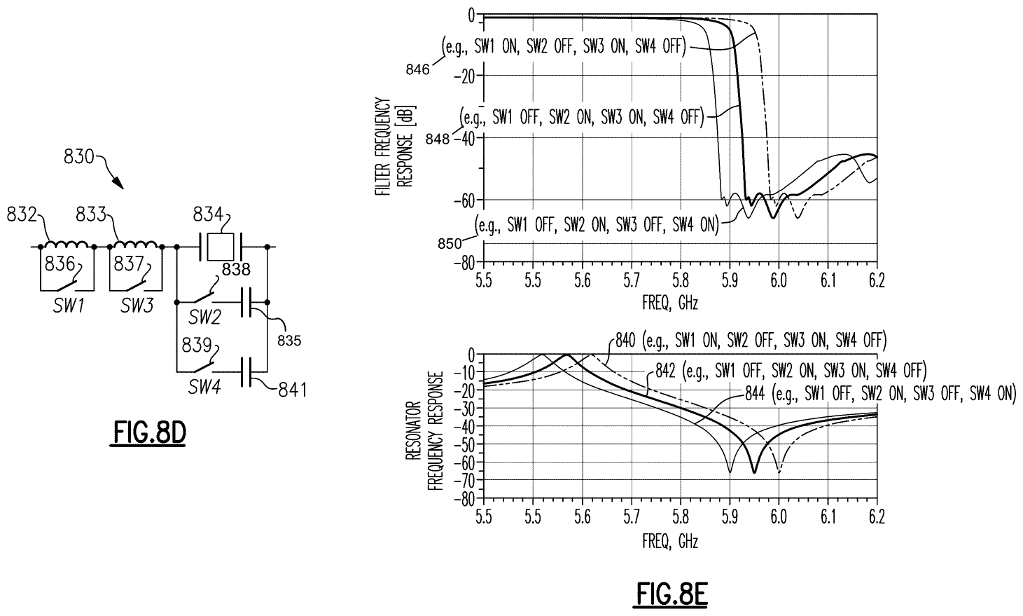

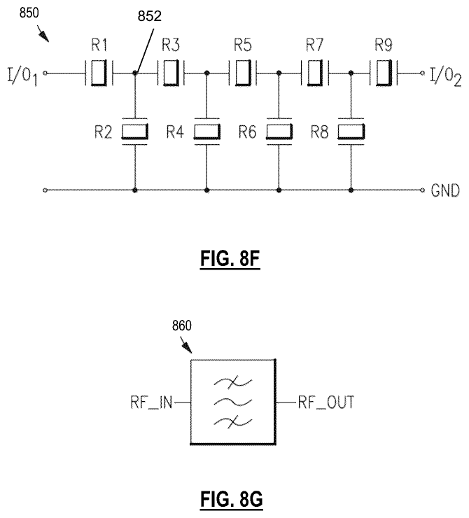

The upper plot of FIG. 8A shows an example of an upper passband roll-off of a bandpass filter frequency response. Such a bandpass filter can be constructed of one or more BAW resonators. The lower plot of FIG. 8A shows an example of a frequency response of an unloaded resonator that can be included in the bandpass filter, where the resonator contributes significantly to the shape of the upper passband roll-off of the bandpass filter.

The position of a filter frequency roll-off and, correspondingly, the filter transition band, can be defined by the position of resonance and anti-resonance in the resonator(s) of the acoustic filter. For example, shifting the resonator frequency response in of the lower plot in FIG. 8A can result in shifting the upper passband frequency response of the filter shown in the upper plot in FIG. 8A.

FIG. 8B illustrates an example of a resonator circuit 810 including an acoustic resonator 814 (e.g., a BAW resonator) with switchable reactive elements. For example, the resonator 810 may form or be included in a passband filter. The circuit 810 includes an inductor 812 that can be selectively included in series with the resonator 814 by opening the switch 816, and a capacitor 820 that can be selectively included in parallel with the resonator 814 by closing the switch 818. The switches 816, 818 can be controlled by circuitry in a front end module or other component that houses the switches 816, 818. For example, referring briefly to FIG. 6, the module front end module 620 can respond to a control signal received from a baseband processor 640 of the SoC 650 to control switches in the filter 605, thereby adjusting the frequency response of the filter 605 and tuning the transition band.

FIG. 8C shows the frequency response of the resonator circuit 810 for different configurations of the switches 816, 818.

FIG. 8C shows that the resonance frequency (fs) and antiresonance frequency (fp) of the resonator circuit 810 can be adjusted with reactive elements such as the inductor 812 and the capacitor 820. Changing fs can be accomplished, for example, by adding the inductor 812 in series with the resonator 814 by opening the switch 816. Changing fp can be accomplished, for example, by adding the capacitor 818 in parallel to the resonator 814 by closing the switch 818.

Plot 820 shows the frequency response of the resonator circuit 810 when the switch 816 is closed (on), thereby excluding the inductor 812, and the switch 818 is open (off), thereby excluding the capacitor 820. As a result of this switching state (STATE 1), fs and fp correspond to the natural frequency response of the resonator 814.

Plot 822 shows the frequency response of the resonator circuit 810 when the switch 816 is closed (on), thereby excluding the inductor 812, and the switch 818 is closed (on), thereby including the capacitor 820. As a result, fs will correspond to the natural frequency response of the resonator 814, and effective fp is shifted down to fp′. As a result of this switch configuration (STATE 2), the upper passband roll-off of a passband filter including the resonator circuit 810 may move down as compared to STATE 1.

Plot 824 shows the frequency response of the resonator circuit 810 when the switch 816 is open (off), thereby including the inductor 812, and the switch 818 is open (off), thereby excluding the capacitor 820. As a result of this switch state (STATE 3), effective fs is shifted down to fs′, whereas fp corresponds to the natural frequency response of the resonator 814. As a result of this switch configuration, the upper passband roll-off of a passband filter including the resonator circuit may move down as compared to STATE 1.

Plot 826 shows the frequency response of the resonator circuit 810 when the switch 816 is open (off), thereby including the inductor 812, and the switch 818 is closed (on), thereby including the capacitor 820. As a result, effective fs shifts down to fs' and effective fp shifts down to fp′. As a result of this switch configuration (STATE 4), the upper passband roll-off of a filter including the resonator circuit 810 may move down as compared to STATE 1, and by a larger amount than results from either of STATES 2 or STATE 3.

FIG. 8D shows an example of a resonator circuit 830 with additional switchable reactive elements. The resonator circuit 830 includes a first inductor 832 that can be included in series with the resonator 834 by opening the switch 836, a second inductor 833 that can be included in series with the resonator 834 by opening the switch 837, a first capacitor 835 that can be included in parallel with the resonator 834 by closing the switch 838, and a second capacitor 841 that can be included in parallel with the resonator 834 by closing the switch 839.

The upper graph of FIG. 8E shows examples of upper passband roll-off of a bandpass filter frequency response of a filter including the resonator circuit 830 for three different switching configurations. The lower graph of FIG. 8E shows examples of the frequency response of the resonator circuit 830, which is included in the bandpass filter.

The plot 840 in the lower graph and the plot 846 in the upper graph correspond to a switching configuration in which the switch 836 is on, thereby excluding the inductor 832, the switch 837 is on, thereby excluding the inductor 833, the switch 838 is off, thereby excluding the capacitor 835, and the switch 839 is off, thereby excluding the capacitor 841. Thus, the plot 846 and the plot 840 correspond to an upper passband roll-off of the filter and a frequency response of the resonator circuit 830 that correspond to the natural frequency response of the resonator 834.

The plot 842 in the lower graph and the plot 848 in the upper graph correspond to a switching configuration in which the switch 836 is off, thereby including the inductor 832, the switch 837 is on, thereby excluding the inductor 833, the switch 838 is on, thereby including the capacitor 835, and the switch 839 is off, thereby excluding the capacitor 841. Thus, the plot 842 reflects a frequency response of the resonator circuit 830 that is shifted down, and the plot 848 shows to a corresponding shifting down of the upper passband roll-off of the filter.

The plot 844 in the lower chart and the plot 850 in the upper chart correspond to a switching configuration in which the switch 836 is off, thereby including the inductor 832, the switch 837 is off, thereby including the inductor 833, the switch 838 is on, thereby including the capacitor 835, and the switch 839 is on, thereby including the capacitor 841. Thus, because additional series inductance and additional parallel capacitance have been incorporated into the resonator circuit 830, the plot 844 reflects to a further shifting down of the frequency response of the resonator circuit 830 as compared to the other switching configurations, and the plot 850 shows to a further corresponding shifting down of the upper passband roll-off of the filter.

While the example resonator circuit 830 includes two inductors and two capacitors, a wide variety of other configurations are possible, such as where the circuit includes three or more inductors, or three or more capacitors. Moreover, while FIGS. 8B and 8D show series connected resonators with switchable inductances and capacitances, bandpass filters compatible with embodiments described herein can additionally include one or more shunt resonators, where one or more of the shunt resonators can include switchable inductor(s) and/or capacitor(s).

An example of a filter topology is shown in FIG. 8F. The filter 850 has a ladder resonator topology that can implement a band pass filter formed of acoustic wave resonators (e.g., BAW resonators). Depending on the embodiment, in a band pass filter with a ladder filter topology, some or all the shunt resonators can have lower resonant frequencies than the series resonators. The ladder filter 850 can be arranged to filter a radio frequency signal.

As illustrated, the ladder filter 850 includes series acoustic wave resonators R1, R3, R5, R7, and R9 and shunt acoustic wave resonators R2, R4, R6, and R8 coupled between a first input/output port I/O₁ and a second input/output port I/O₂. Any suitable number of series acoustic wave resonators and shunt acoustic wave resonators can be included in a ladder filter.

The first input/output port I/O₁ can be a transmit port and the second input/output port I/O₂ can be an antenna port. Alternatively, first input/output port I/O₁ can be a receive port and the second input/output port I/O₂ can be an antenna port. One or more of the acoustic resonators of the ladder filter 850 can include a an acoustic resonator having switchable inductances and/or capacitances in accordance with any suitable principles and advantages disclosed herein.

For example, one or more of the series resonators R1, R3, R5, R7, R9 can be resonator circuits similar to the resonator circuit 810 of FIG. 8B, or the resonator circuit 830 of FIG. 8D, including switchable inductor(s) and capacitor(s). In such cases, the switchable inductors and capacitors corresponding to one or more of the series resonators can be controlled to adjust the response of the bandpass filter, e.g., to adjust the upper bandpass roll-off as described with respect FIGS. 8A-8E. As one example, referring to the series resonator R1, one or more switchable inductors could be connected in series between I/O₁ and R1, and one or more switchable capacitors could be connected in parallel with R1. Moreover, one or more of the shunt resonators R2, R4, R6, R8 can be resonator circuits similar to the resonator circuit 810 of FIG. 8B, or the resonator circuit 830 of FIG. 8D, including switchable inductor(s) and capacitor(s). In such cases, the switchable inductors and capacitors corresponding to one or more of the series resonators can be controlled to adjust the response of the bandpass filter, e.g., to adjust the lower bandpass roll-off as described with respect FIGS. 8A-8E. As one example, referring to the shunt resonator R2, one or more inductors could be connected in series between the node 852 and R2, and one or more capacitors could be connected in parallel with R2. R1 and R2 are just used as two examples. Depending on the embodiment, any combination of R1-R9 can have one or more corresponding switchable inductors (e.g., in series with the corresponding resonator) and one or more corresponding switchable capacitors (e.g., in parallel with the corresponding resonator).

In some embodiments, one or more of the series resonators can contribute significantly to defining the upper roll-off of the frequency response of the bandpass filter 850, and one or more of the shunt resonators can contribute to defining the lower roll-off of the frequency response of the bandpass filter 850.

A filter that includes an acoustic wave resonator (e.g., a BAW or SAW resonator) in accordance with any suitable principles and advantages disclosed herein be arranged to filter a radio frequency signal, e.g., in a Wi-Fi 5 GHz or 6 GHz operating band. For example, referring to FIGS. 6 and 7A, when it is desired to communicate in UNII-4 (e.g., in 5 GHz channel 169, 173, 177), the front end module 620 can be configured by the baseband processor 640 or other appropriate component to control the 5 GHz filter 605 to adjust the location of the transition band by selectively controlling the switched in capacitance and/or inductance for at least one resonator (e.g., a series resonator) of the 5 GHz filter 605, thereby increasing the upper passband roll-off of the 5 GHz filter 605. Moreover, the front end module 620 can additionally be configured by the baseband processor 640 to control the 6 GHz filter 605′ to adjust the location of the transition band by selectively controlling the switched in capacitance and/or inductance for at least one resonator (e.g., a shunt resonator) of the 6 GHZ filter 605′, thereby increasing the lower passband roll-off of the 6 GHz filter 605′. During this operating mode (e.g., when operating in UNII-4), the baseband processor 640 or other appropriate component can be configured to disallow or blacklist communication on certain communication bands, including any of the following for example (see FIG. 2): 20 MHZ channel 1, 5, 9, 40 MHz channels 3 and 11, 80 MHz channel 7, 160 MHz channel 15, and 320 MHz channel 31; any channel that extends into the frequency range from 5945 to 6005.

Moreover, referring now to FIGS. 6 and 7B, when it is desired to communicate in the lower part of the UNII-5 band (e.g., in 6 GHz channel 1, 5, or 9), the front-end module 620 can be configured by the baseband processor 640 or other appropriate component to control the 5 GHz filter 605 to adjust the location of the transition band by selectively controlling the switched in capacitance and/or inductance for at least one resonator (e.g., a series resonator) of the 5 GHz filter 605, thereby reducing the upper passband roll-off of the 5 GHz filter 605. Moreover, the front end module 620 can additionally be configured by the baseband processor 640 to control the 6 GHz filter 605′ to adjust the location of the transition band by selectively controlling the switched in capacitance and/or inductance for at least one resonator (e.g., a shunt resonator) of the 6 GHz filter 605′, thereby reducing the lower passband roll-off of the 6 GHz filter 605′. During this operating mode (e.g., operating in lower UNII-5 channels 1, 5, and 9), the baseband processor 640 or other appropriate component can be configured to disallow or blacklist communication on certain communication bands, including any of the following for example (see FIG. 2): 20 MHz channel 169, 173, 177, 40 MHz channels 167 and 175, 80 MHz channel 171, and 160 MHz channel 163; any 5 GHZ channel that extends into the frequency range between 5835 and 5895 MHz.

FIG. 8G is a schematic diagram of an acoustic wave bandpass filter 860. The acoustic wave filter 860 can include the acoustic wave resonators of the ladder filter 850, or a filter having another topology, such as a lattice structure, for example. The acoustic wave filter 860 is a band pass filter. The acoustic wave filter 860 includes one or more acoustic wave devices (e.g., BAW or SAW resonators) coupled between a first input/output port RF_IN and a second input/output port RF_OUT.

While embodiments have been described in connection with BAW resonators, alternative embodiments can include other types of acoustic devices, such as one or more surface acoustic wave (SAW) resonators, instead of or in addition to BAW resonators.

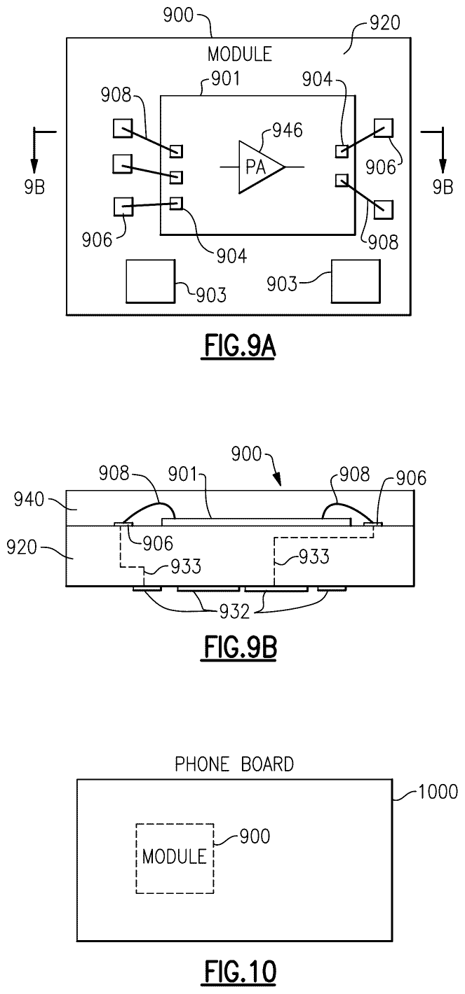

FIG. 9A is a schematic diagram of one embodiment of a packaged module 900. FIG. 9B is a schematic diagram of a cross-section of the packaged module 900 of FIG. 9A taken along the lines 9B-9B.

The packaged module 900 includes an IC or die 901, surface mount components 903, wirebonds 908, a package substrate 920, and encapsulation structure 940. The package substrate 920 includes pads 906 formed from conductors disposed therein. Additionally, the die 901 includes pads 904, and the wirebonds 908 have been used to electrically connect the pads 904 of the die 901 to the pads 906 of the package substrate 901.

The die 901 includes a power amplifier 946, which can be implemented in accordance with any of the embodiments herein.

The packaging substrate 920 can be configured to receive a plurality of components such as the die 901 and the surface mount components 903, which can include, for example, surface mount capacitors and/or inductors.

As shown in FIG. 9B, the packaged module 900 is shown to include a plurality of contact pads 932 disposed on the side of the packaged module 900 opposite the side used to mount the die 901. Configuring the packaged module 900 in this manner can aid in connecting the packaged module 900 to a circuit board such as a phone board of a wireless device. The example contact pads 932 can be configured to provide RF signals, bias signals, power low voltage(s) and/or power high voltage(s) to the die 901 and/or the surface mount components 903. As shown in FIG. 9B, the electrically connections between the contact pads 932 and the die 901 can be facilitated by connections 933 through the package substrate 920. The connections 933 can represent electrical paths formed through the package substrate 920, such as connections associated with vias and conductors of a multilayer laminated package substrate.

In some embodiments, the packaged module 900 can also include one or more packaging structures to, for example, provide protection and/or facilitate handling of the packaged module 900. Such a packaging structure can include overmold or encapsulation structure 940 formed over the packaging substrate 920 and the components and die(s) disposed thereon.

It will be understood that although the packaged module 900 is described in the context of electrical connections based on wirebonds, one or more features of the present disclosure can also be implemented in other packaging configurations, including, for example, flip-chip configurations.

FIG. 10 is a schematic diagram of one embodiment of a phone board 1000. The phone board 1000 includes the module 900 shown in FIGS. 9A-9B attached thereto. Although not illustrated in FIG. 9 for clarity, the phone board 900 can include additional components and structures.

### Applications

Some of the embodiments described above have provided examples in connection with wireless devices or mobile phones. However, the principles and advantages of the embodiments can be used for any other systems or apparatus that have needs for power amplifiers.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. An acoustic filter assembly for operating at a target band including multi sub-target bands and a spacing between the multi target sub-bands, the acoustic filter assembly comprising:
a first filter configured to allow signals to pass at a first band;
a second filter configured to allow the signals to pass at a second band, the first filter and the second filter being configured to have a transition band between the first band and the second band, the transition band being wider than the spacing of the target band; and
an interface configured to receive a control signal that controls the transition band to be shifted between a first position and a second position, an upper part of a lower sub-target band being covered by the first band in the first position, and a lower part of an upper sub-target band being covered by the second band in the second position.

2. The acoustic filter assembly of claim 1 wherein the width of the transition band is less than or equal to 110 MHz.

3. The acoustic filter assembly of claim 1 wherein, in the first position, a lower edge of the transition band is aligned with a lower end of the spacing.

4. The acoustic filter assembly of claim 1 wherein, in the second position, an upper edge of the transition band is aligned with an upper end of the spacing.

5. The acoustic filter assembly of claim 1 wherein the target band is used as an unlicensed band.

6. The acoustic filter assembly of claim 1 wherein the spacing of the target band is located between 5895 MHz and 5945 MHz.

7. The acoustic filter assembly of claim 1 wherein each of the first filter and the second filter includes at least one resonator, which is selectively connected with a reactive element by the control signal to adjust a resonance frequency or an anti-resonance frequency of the resonator.

8. The acoustic filter assembly of claim 7 wherein the reactive element is at least one of a capacitor and an inductor.

9. The acoustic filter assembly of claim 1 wherein a location of the transition band is shifted using a RF cancellation that involves adding a phase-inverted signal according to the control signal.

10. A radio frequency module comprising:
a packaging substrate configured to receive a plurality of components;
an acoustic filter assembly for a target band including multi sub-bands and a spacing between the multi sub-bands, the acoustic filter assembly implemented on the packaging substrate, the acoustic filter assembly including a first filter configured to allow signals to pass at a first band, a second filter configured to allow the signals to pass at a second band, the first filter and the second filter being configured to have a transition band between the first band and the second band, the transition band being wider than the spacing of the target band, and an interface configured to receive a control signal that controls the transition band to be shifted between a first position and a second position, an upper part of lower sub-target band being covered by the first band in the first position, a lower part of an upper sub-target band being covered by the second band in the second position; and
a controller configured to provide the control signal.

11. The radio frequency module of claim 10 wherein the radio frequency module is a front-end module.

12. The radio frequency module of claim 10 wherein the width of the transition band is less than or equal to 110 MHz.

13. The radio frequency module of claim 10 wherein, in the first position, a lower edge of the transition band is aligned with a lower end of the spacing.

14. The radio frequency module of claim 10 wherein, in the second position, an upper edge of the transition band is aligned with an upper end of the spacing.

15. The radio frequency module of claim 10 wherein the target band is used as an unlicensed band.

16. The radio frequency module of claim 10 wherein the spacing of the target band is located between 5895 MHz and 5945 MHz.

17. The radio frequency module of claim 10 wherein each of the first filter and the second filter includes at least one resonator, which is selectively connected with a reactive element by the control signal to adjust a resonance frequency or an anti-resonance frequency of the resonator.

18. The radio frequency module of claim 17 wherein the reactive element is at least one of a capacitor and an inductor.

19. The radio frequency module of claim 10 wherein the transition band is switched using a RF cancellation that involves adding a phase-inverted signal according to the control signal.

20. A wireless device comprising:
a transceiver configured to generate a radio frequency signal; and
a front end system including an acoustic filter assembly for a target band including multi sub-bands and a spacing between the multi sub-bands, the acoustic filter assembly including a first filter configured to allow signals to pass at a first band, a second filter configured to allow the signals to pass at a second band, the first filter and the second filter configured such to have a transition band between the first band and the second band, the transition band being wider than the spacing of the target band, and an interface configured to receive a control signal that controls the transition band to be shifted between a first position and a second position, an upper part of lower sub-target band is covered by the first band in the first position, a lower part of an upper sub-target band is covered by the second band in the second position.
